(19) United States
(12) Patent Application Publication
(10) Pub. No.: US 2025/0055424 A1
(43) Pub. Date: Feb. 13, 2025

(54) PREAMPLIFIER WITH ACTIVE DEADTIME CONTROL CIRCUIT AND METHOD FOR DRIVING THE SAME

(71) Applicant: UNIVERSITY INDUSTRY FOUNDATION, YONSEI UNIVERSITY WONJU CAMPUS, Wonju-si (KR)

(72) Inventors: In Yong KWON, Seoul (KR); Min Uk SEUNG, Daejeon (KR)

(21) Appl. No.: 18/792,474

(22) Filed: Aug. 1, 2024

(30) Foreign Application Priority Data
Aug. 10, 2023 (KR) 10-2023-0104843

(51) Int. Cl. H03F 1/52; H03F 3/45

(52) U.S. Cl. CPC H03F 1/52; H03F 3/45475

(57) ABSTRACT

Provided is a preamplifier with an active deadtime control circuit, which may include: an operational amplifier to which input current and common voltage are applied; a feedback capacitor of which both ends are connected to a first input terminal of the operational amplifier to which the input current is applied and an output terminal of the operational amplifier; a comparator comparing output voltage converted from the input current by the operational amplifier, and reference voltage to output a comparison signal; and a Monostable circuit outputting a switching signal for switching charging or discharging of the feedback capacitor based on the comparison signal.

### CROSS-REFERENCE TO RELATED APPLICATIONS

This application claims the priority of Korean Patent Application No. 10-2023-0104843filed on 10 Aug. 2023, in the Korean Intellectual Property Office, the disclosure of which is incorporated herein by reference.

### BACKGROUND

### Field

The present disclosure relates to a preamplifier with an active deadtime control circuit and a method for driving the same.

### Description of the Related Art

FIG. 1 is a schematic configuration diagram of a preamplifier in related art. Referring to FIG. 1, a charge-sensitive amplifier (CSA) which is a preamplifier most universally used in a radiation instrument reading system is configured in a form in which a resistor and a feedback capacitor CF are connected to feedback of an operating amplifier.

The CSA serves to convert a current signal generated by a radiation instrument into a voltage form, and amplify the voltage form, and since the CSA is disposed at a frontmost end of the radiation instrument reading system, and extracts a signal, the CSA exerts a direct influence on signal-to-noise radio (SNR), measurement efficiency, and energy resolution. Further, since an output of the CSA is in proportion to the amount of charge of the input current signal, the output of the CSA has a high energy resolution.

However, in a high radiation environment, the radiation instrument generates a signal (current signal) at a very fast speed, and in this case, the charge is not discharged, but is continuously accumulated in the feedback capacitor CF, which consequently causes output saturation, thereby causing an error of an entire system. Such an output saturation phenomenon is referred to as a pile-up phenomenon.

FIG. 2 is a graph illustrating a pile-up phenomenon which is enabled to occur when using the preamplifier in the related art. Referring to FIG. 2, a phenomenon may be seen in which the feedback capacitor CF is not sufficiently discharged by the input current signal, so the output is saturated.

In general, in order to prevent the pile-up phenomenon, a self-initialization circuit is used. However, in the high radiation environment, since the current signal is input into the preamplifier at the very fast speed as described above, the input current signal is omitted while the preamplifier is initialized, so the number of signals extracted (measured) by the preamplifier is smaller than signals (current signals) actually generated by the radiation instrument, and as a result, the measurement efficiency deteriorates. At this time, a time period in which the signal is not measured due to initialization is referred to as deadtime.

FIG. 3 is a graph illustrating deterioration of measurement efficiency due to deadtime which is enabled to occur when using the preamplifier in the related art. Referring to FIG. 3, it can be seen that there is a difference between a true count rate for an actual input signal and a measured count rate for a measured signal.

A technology which becomes a background of the present disclosure is disclosed in Korean Patent Registration No. 10-1686306.

### SUMMARY

According to an exemplary embodiment of the present disclosure, the Monostable circuit may include a first logic device receiving the comparison signal and the switching signal, a Monostable capacitor having one end connected to an output terminal of the first logic device, and charged or discharged based on an output signal of the first logic device, and a second logic circuit having an input terminal connected to the Monostable capacitor, and receiving an input signal inverted according to a charging or discharging state of the Monostable capacitor through the input terminal, and outputting the switching signal.

According to an exemplary embodiment of the present disclosure, the Monostable capacitor may be charged when the output signal is low and discharged when the output signal is high.

According to an exemplary embodiment of the present disclosure, the preamplifier may further include a switch device having both ends connected to the first input terminal of the operational amplifier and the output terminal of the operational amplifier and switching charging or discharging of the feedback capacitor by inputting the switching signal.

According to an exemplary embodiment of the present disclosure, the operational amplifier may receive the input current generated from a radiation instrument through the first input terminal of the operational amplifier, and receive the common voltage through a second input terminal of the operational amplifier.

As a technical means for achieving the technical object, according to an exemplary embodiment of the present disclosure, there is provided a method for driving a preamplifier with an active deadtime control circuit, which may include: (a) applying input current and common voltage to an operational amplifier; (b) outputting a comparison signal through a comparator comparing output voltage converted from the input current by the operational amplifier, and reference voltage; and (c) outputting a switching signal for switching charging or discharging of a feedback capacitor having both ends connected to a first input terminal of the operational amplifier, to which the input current is applied, and an output terminal of the operational amplifier based on the comparison signal, through a Monostable circuit.

According to an exemplary embodiment of the present disclosure, step (c) may include (c-1) inputting the comparison signal and the switching signal into a first logic device, and (c-2) connecting a Monostable capacitor having one end connected to an output terminal of the first logic device, and charged or discharged based on an output signal of the first logic device to an input terminal, and receiving an input signal inverted according to a charging or discharging state of the Monostable capacitor through the input terminal, and outputting the switching signal through a second logic device.

According to an exemplary embodiment of the present disclosure, the Monostable capacitor may be charged when the output signal is low and discharged when the output signal is high.

According to an exemplary embodiment of the present disclosure, the method may further include (d) inputting the switching signal into a switch device having both ends connected to the first input terminal of the operational amplifier and the output terminal of the operational amplifier, and switching charging or discharging of the feedback capacitor.

According to an exemplary embodiment of the present disclosure, the operational amplifier may receive the input current generated from a radiation instrument through the first input terminal of the operational amplifier, and receive the common voltage through a second input terminal of the operational amplifier.

The above-described task resolution means is only an exemplary and should not be interpreted as the intention to restrict the present disclosure. In addition to the exemplary embodiments described above, there may be additional exemplary embodiments in drawings and the detailed description of the present disclosure.

According to the solving means of the present disclosure described above, there is an effect in that a circuit is initialized by using a comparator and a Monostable circuit to prevent saturation of an output signal in a high radiation environment in which a large amount of radiation is generated.

According to the solving means of the present disclosure described above, there is an effect in that a deadtime in which input current is omitted upon circuit initialization is reduced by reducing a duration of an output pulse through incomplete discharge of a Monostable capacitor to enhance radiation measurement efficiency and power efficiency.

However, the effects that can be obtained herein are not limited to the effects described above, and there may be other effects.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration diagram of a preamplifier in related art;

FIG. 2 is a graph illustrating a pile-up phenomenon which is enabled to occur when using the preamplifier in the related art;

FIG. 3 is a graph illustrating deterioration of measurement efficiency due to deadtime which is enabled to occur when using the preamplifier in the related art;

FIG. 4 is a schematic circuit diagram of a preamplifier with an active deadtime control circuit according to an exemplary embodiment of the present disclosure;

FIG. 5 is a timing diagram for describing a schematic operation principle of the preamplifier with an active deadtime control circuit according to an exemplary embodiment of the present disclosure;

FIG. 6 is a diagram illustrating a simulation result of the preamplifier with an active deadtime control circuit according to an exemplary embodiment of the present disclosure;

FIG. 7 is a diagram illustrating a validation result of an active deadtime control result of the preamplifier with an active deadtime control circuit according to an exemplary embodiment of the present disclosure;

FIG. 8 is a diagram for comparing power consumption for the preamplifier with an active deadtime control circuit according to an exemplary embodiment of the present disclosure and a preamplifier having a constant deadtime in the related art;

FIG. 9 is an operation flowchart for a method for driving the preamplifier with an active deadtime control circuit according to an exemplary embodiment of the present disclosure; and

FIG. 10 is an operation flowchart for a method for driving a Monostable circuit of the preamplifier with an active deadtime control circuit according to an exemplary embodiment of the present disclosure.

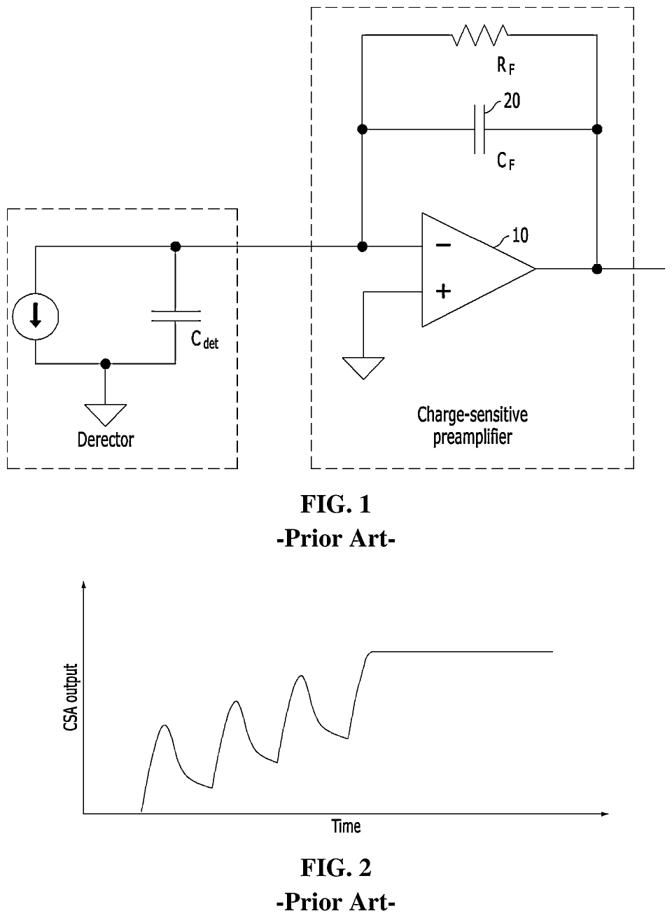

### DETAILED DESCRIPTION OF THE EMBODIMENT

Hereinafter, exemplary embodiments of the present disclosure will be described in detail so as to be easily implemented by those skilled in the art, with reference to the accompanying drawings. However, the present disclosure may be implemented in various different forms and is not limited to exemplary embodiments described herein. In addition, in the drawings, in order to clearly describe the present disclosure, a part not related to the description is omitted and like reference numerals designate like elements throughout the present specification.

Throughout the specification of the present disclosure, when it is described that a part

is “connected” with another part, it means that the certain part may be “directly connected” with another part and the elements “electrically connected” or “indirectly connected” to each other with a third element interposed therebetween as well.

Throughout the specification of the present disclosure, it will be understood that when a member is referred to as being “on”, “at an upper portion of”, “on the top of”, “beneath”, “at a lower portion of”, and “on the bottom of” another member, it can be directly on the other member, or intervening members may also be present.

Throughout the present specification of the present disclosure, unless explicitly described to the contrary, a case where any part “includes” any component will be understood to imply the inclusion of stated components but not the exclusion of any other component.

The present disclosure relates to a preamplifier with an active deadtime control circuit. The preamplifier 100 with an active deadtime control circuit according to an exemplary embodiment of the present disclosure may be implemented to actively control a deadtime according to a radiation environment by using a comparator 130 and a Monostable circuit 140 in order to reduce a pile-up phenomenon which occurs in a preamplifier in related art.

Hereinafter, for describing the circuit, the description will be made by denoting a node or terminal connected by one edge (wire) and short-circuited from each other by reference numerals a to h. In other words, the nodes short-circuited from each other may be described by using the same reference numeral.

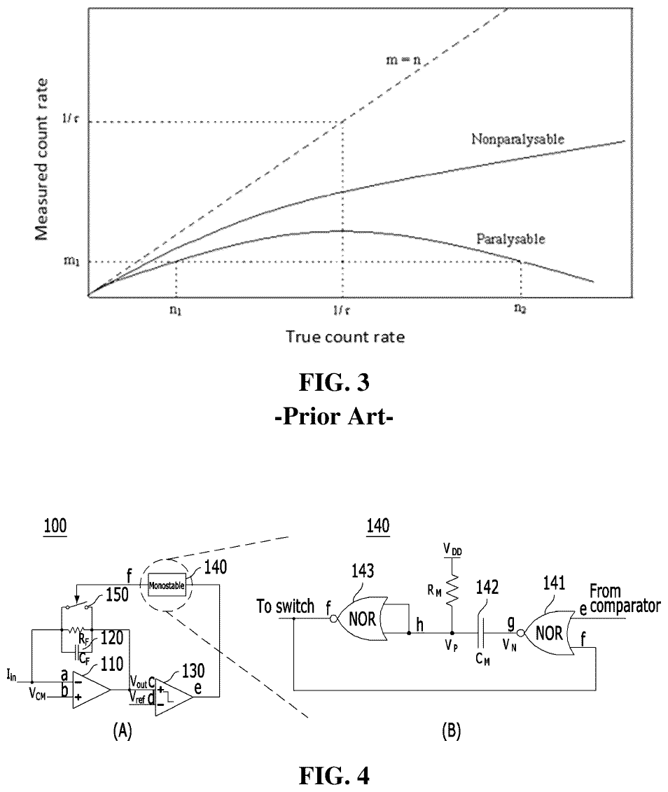

FIG. 4 is a schematic circuit diagram of a preamplifier with an active deadtime control circuit according to an exemplary embodiment of the present disclosure.

Hereinafter, for convenience of description, the ‘preamplifier 100 with an active deadtime control circuit’ according to an exemplary embodiment of the present disclosure will be specified as the ‘preamplifier 100’.

Referring to FIG. 4, the preamplifier 100 may include an operational amplifier 110, a feedback capacitor 120, a comparator 130, a Monostable circuit 140, and a switch device 150.

Referring to FIG. 4, the operational amplifier 110 may be applied with input current i_{In} and common voltage V_{CM}. Specifically, the operational amplifier 110 may include a first input terminal a and a second input terminal b, and the input current i_{In} generated by a radiation instrument may be applied to the first input terminal a, and the common voltage V_{CM} may be applied to the second input terminal b.

Further, referring to FIG. 4, the operational amplifier 110 may include an output terminal c, and output voltage V_{Out} converted from the input current i_{In} may be output through the output terminal c.

Referring to FIG. 4, both ends of the feedback capacitor (C_{F}) 120 may be connected to the first input terminal a and the output terminal c of the operational amplifier 110. Further, both ends of a feedback resistor R_{F} may be further connected to the first input terminal a and the output terminal c of the operational amplifier 110. That is, the feedback capacitor (C_{F}) 120 and the feedback resistor R_{F} may be connected to each other in parallel.

Referring to FIG. 4, the comparator 130 compares the output voltage V_{Out} converted from the input current inn by the operational amplifier 110, and reference voltage V_{ref} to output a comparison signal. In other words, the comparator 130 may include an input terminal c connected to the output terminal c of the operational amplifier 110, an input terminal d to which the reference voltage V_{ref} is applied, and an output terminal e outputting the comparison signal.

Specifically, when the output voltage V_{Out} output by the operational amplifier 110 as the input current inn is generated at a fast speed from the radiation instrument and the charge is accumulated in the feedback capacitor (C_{F}) 120 exceeds the reference voltage V_{ref}, the comparator 130 may output a high signal as the comparison signal, and when the output voltage V_{Out} is less than the reference voltage V_{ref}, the comparator 130 may output a low signal as the comparison signal.

Referring to FIG. 4, the Monostable circuit 140 may output a switching signal for switching charging or discharging of the feedback capacitor (C_{F}) 120 based on the comparison signal output by the comparator 130. In other words, an input terminal e of the Monostable circuit 140 may be connected to the output terminal e of the comparator 130, and an output terminal f of the Monostable circuit 140 may be connected to an input terminal of the switch device 150 to be described below.

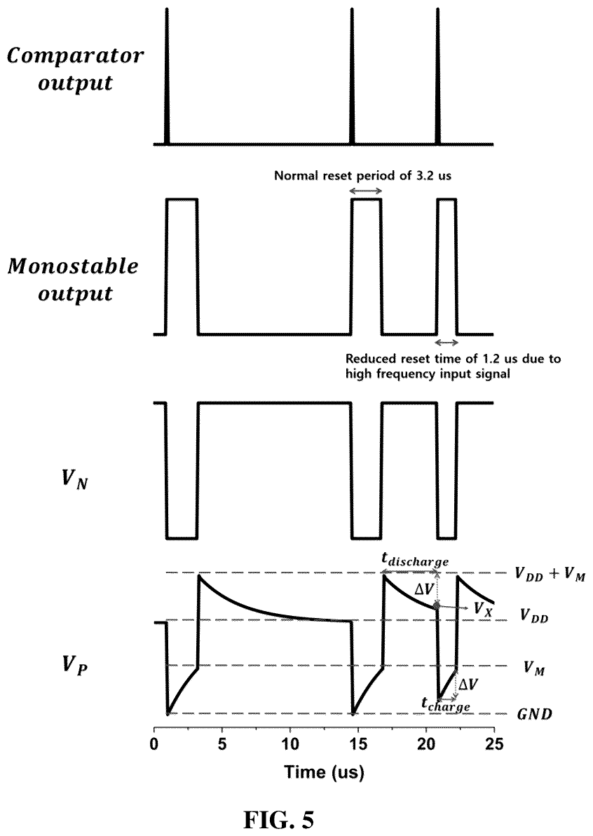

Specifically, when the Monostable circuit 140 receives the comparison signal which becomes the high signal by the high radiation environment, the Monostable circuit 140 discharges the feedback capacitor (C_{F}) 120 to initialize the preamplifier 100, and may control the deadtime while the preamplifier 100 is initialized according to a speed at which the comparison signal is switched to the high signal, that is, according to a speed at which the input current inn is generated in the radiation instrument by the high radiation environment. The Monostable circuit 140 will be described below in more detail with reference to FIGS. 4 and 5.

Referring to FIG. 4, the switch device 150 may switch the charging or discharging of the feedback capacitor (C_{F}) 120 by inputting the switching signal output by the Monostable circuit 140. Specifically, both ends of the switch device 150 may be connected to the first input terminal a of the operational amplifier 110 and the output terminal c of the operational amplifier 110, and the input terminal f for switching may be connected to the output terminal f of the Monostable circuit 140. In other words, the switch device 150 may be connected to the feedback capacitor (C_{F}) 120 and the feedback resistor R_{F}.

Specifically, the switch device 150 is switched to ON to discharge the feedback capacitor (C_{F}) 120 when the switching signal output by the Monostable circuit 140 is the high signal, and switched to OFF to allow the preamplifier 100 to extract a radiation measurement signal again when the switching signal is the low signal. In other words, the switching signal which is the high signal may be a ‘reset signal’ that initializes the preamplifier 100 by discharging the feedback capacitor (C_{F}) 120.

Meanwhile, referring to FIG. 4, the Monostable circuit 140 may include a first logic device 141, a Monostable capacitor (C_{M}) 142, and a second logic device 143.

At this time, the first logic device 141 and the second logic device 143 may be NOR gates. Further, referring to FIG. 4, the input terminal of the Monostable circuit 140 may be a first input terminal e of the first logic device 141, and the output terminal of the Monostable circuit 140 may be an output terminal f of the second logic device 143.

Meanwhile, the Monostable capacitor (C_{M}) 142 which means a capacitor included in the Monostable circuit 140 is expressed as a Monostable capacitor, and a role of Monostable is not assigned to the capacitor itself.

Referring to FIG. 4, the first logic device 141 may include a first input terminal e receiving the comparison signal, and a second input terminal f receiving the switching signal as a feedback input signal.

Referring to FIG. 4, one end of the Monostable capacitor (C_{M}) 142 may be connected to an output terminal g of the first logic device 141, and the other end may be connected to an input terminal h of the second logic device 143. Further, the Monostable capacitor (C_{M}) 142 may be charged or discharged based on an output signal of the first logic device 141.

Referring to FIG. 4, the input terminal h of the second logic device 143 is connected to the other end of the Monostable capacitor (C_{M}) 142 to receive an input signal inverted according to a charging or discharging state of the Monostable capacitor (C_{M}) 142 through the input terminal h, and output the switching signal through the output terminal f.

Hereinafter, an operation principle of the Monostable circuit 140 will be described in detail with reference to FIGS. 4 and 5.

FIG. 5 is a timing diagram for describing a schematic operation principle of the preamplifier with an active deadtime control circuit according to an exemplary embodiment of the present disclosure.

Referring to FIGS. 4 and 5, as described above, when the output voltage V_{Out} exceeds the reference voltage V_{ref} by the input current inn generated at the fast speed in the high radiation environment, the comparison signal output by the comparator 130 becomes the high signal. At this time, the comparison signal which is the high signal is applied to the first input terminal e of the first logic device 141, and the first logic device 141 outputs the low signal according to a logic table of the NOR gate.

Here, according to a conservation law of electrical charge, a voltage difference between first voltage V_{N} and second voltage V_{P} applied to both ends of the Monostable capacitor (C_{M}) 142 should become 0 (V_{N}−V_{P}=0), when the first voltage V_{N} applied to the output terminal g of the first logic device 141 is the low signal, the second voltage V_{P} also becomes the low signal.

Meanwhile, referring to FIG. 4, power voltage V_{DD} may be connected to the other end of the Monostable capacitor (C_{M}) 142. Further, referring to FIG. 5, as the second voltage V_{P} becomes the low signal, current flows toward the second voltage V_{P} from the power voltage V_{DD}, and as a result, the charge may be charged in the Monostable capacitor (C_{M}) 142. In other words, the Monostable capacitor (C_{M}) 142 may be charged when an output signal of the first logic device 141 is the low signal.

While the charge is charged in the Monostable capacitor (C_{M}) 142, the low signal is applied to the input terminal h of the second logic device 143 according to the second voltage V_{P} which is the low signal, and the second logic device 143 outputs the high signal according to the logic table of the NOR gate.

At this time, since the output terminal f of the second logic device 143 is the output terminal f of the Monostable circuit 140, and the output signal of the second logic device 143 is the switching signal, the high signal may be input into the switch device 150, and the feedback capacitor (C_{F}) 120 may be discharged and the preamplifier 100 may be initialized.

Thereafter, when the charge is sufficiently charged in the Monostable capacitor (C_{M}) 142, and the second voltage V_{P} exceeds a predetermined threshold voltage V_{M}, the signal of the second voltage V_{P} is inverted from the low signal to the high signal, and the high signal is applied to the input terminal h of the second logic device 143, and the second logic device 143 outputs the low signal according to the logic table of the NOR gate. Here, the predetermined threshold voltage V_{M} may be ideally at a level of ½ of the power voltage V_{DD}, but is not limited thereto.

At this time, as the low signal is input into the switch device 150, and the preamplifier 100 is stabilized after initialization, an output voltage V_{Out} of the operational amplifier 110 decreases to the reference voltage V_{ref} or less, and the comparison signal of the comparator 130 also becomes the low signal. Further, only the low signal is applied to the first logic device 141 receiving the comparison signal, and an output signal of the second logic device 143, so the first logic device 141 outputs the high signal according to the logic table of the NOR gate as illustrated in FIG. 5.

As a result, the first voltage V_{N} and the second voltage V_{P} become the high signals, and as illustrated in FIG. 5, since the second voltage V_{P} increases to the predetermined threshold voltage V_{M} by charging the Monostable capacitor (C_{M}) 142, the second voltage V_{P} may increase up to a level at which the power voltage V_{DD} and the predetermined threshold voltage V_{M} are added.

Further, as the first voltage V_{N} and the second voltage V_{P} become the high signals, the charge of the Monostable capacitor (C_{M}) 142 may be gradually discharged. That is, the Monostable capacitor (C_{M}) 142 may be discharged when the output signal of the first logic device 141 is the high signal.

However, in the high radiation environment, the input current inn is generated very rapidly, and as a result, the comparison signal which is the high signal may be applied to the first logic device 141 again before the Monostable capacitor (C_{M}) 142 is completely discharged.

When the comparison signal which is the high signal is applied to the first logic device 141 before the Monostable capacitor (C_{M}) 142 is completely discharged, a time required for the second voltage V_{P} to increase to the predetermined threshold voltage V_{M}, i.e., a time for which the Monostable capacitor (C_{M}) 142 is charged may be reduced.

Specifically, as the comparison signal which is the low signal is applied to the first logic device 141, the second voltage V_{P} may increase up to a level of V_{DD}+V_{M}, and then the Monostable capacitor (C_{M}) 142 may be discharged, and the second voltage V_{P} may decrease up to a level of V_{DD}. However, when the comparison signal which is the high signal is applied to the first logic device 141 before the Monostable capacitor (C_{M}) 142 is completely discharged, the second voltage V_{P} may only decrease up to a level of V_{X}(V_{DD}<V_{X}<V_{DD}+V_{M}), the second voltage V_{P} becomes the low signal, so the voltage does not decrease up to GND even in the low signal, but may decrease only up to a level of V_{X}−V_{DD}.

In other words, a variation amount ΔV of the second voltage V_{P} by the discharge of the Monostable capacitor (C_{M}) 142 may be smaller than (V_{DD}+V_{M})−V_{DD}, and the second voltage V_{P} may reach the predetermined threshold voltage V_{M} only by charging as much as a voltage variation amount ΔV by discharging even upon charging the Monostable capacitor (C_{M}) 142.

As a result, a time required for the second voltage V_{P} to increase up to the predetermined threshold voltage V_{M}, i.e., a time for which the Monostable capacitor (C_{M}) 142 is charged is reduced, and the comparison signal which is the high signal is applied, and then a time during initialization of the preamplifier 100 is reduced, and thus the deadtime is reduced.

As described above, according to an exemplary embodiment of the present disclosure, the faster the input current i_{In} is generated, the faster a period in which the comparison signal is output as the high signal, and as a result, charging of the Monostable capacitor (C_{M}) 142 is started again before the Monostable capacitor (C_{M}) 142 is completely discharged, so a time required for initializing the preamplifier 100 is reduced, thereby reducing the deadtime.

In other words, according to an exemplary embodiment of the present disclosure, the preamplifier 100 may control the deadtime according to a generation speed of the input current i_{In}.

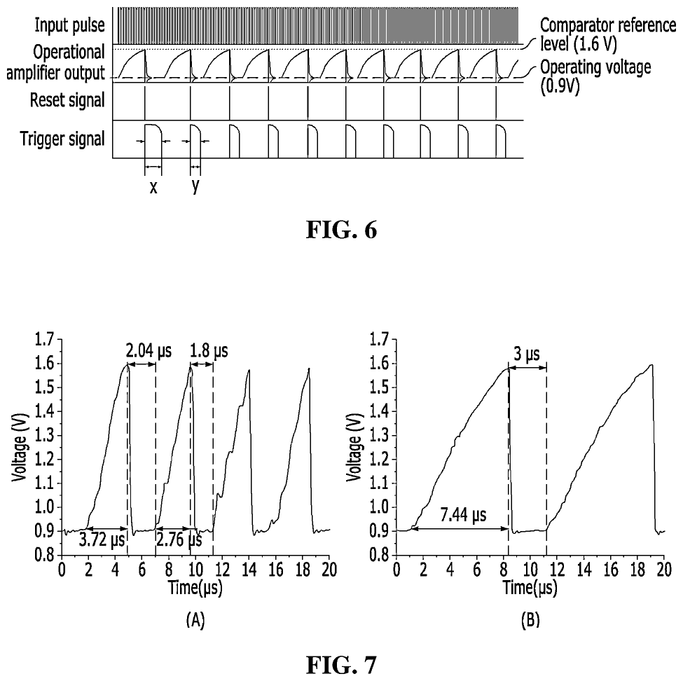

FIG. 6 is a diagram illustrating a simulation result of the preamplifier with an active deadtime control circuit according to an exemplary embodiment of the present disclosure.

Referring to FIG. 6, when an output of the preamplifier 100, i.e., an output of the operational amplifier 110 is increased and saturated to a comparator reference level or more at which the comparator 130 is inverted, a first reset signal as a trigger signal generates a pulse x having a long duration due to a state in which there is no charge in the Monostable capacitor (C_{M}) 142, but a subsequent reset signal as the trigger signal may generate a pulse y having a relatively shorter duration than a first pulse x due to a state in which the Monostable capacitor (C_{M}) 142 is charged with some charges by incomplete discharging of the Monostable capacitor (C_{M}) 142 when the output of the operational amplifier 110 is saturated.

FIG. 7 is a diagram illustrating a validation result of an active deadtime control result of the preamplifier with an active deadtime control circuit according to an exemplary embodiment of the present disclosure.

In FIG. 7, a horizontal axis may represent a time, and a vertical axis may represent the output of the preamplifier 100, i.e., the output voltage V_{Out} of the operational amplifier 110.

Referring to FIG. 7, it can be seen that in output data of the preamplifier 100 according to an exemplary embodiment of the present disclosure, a time for which the output voltage V_{Out} is saturated according to the generation speed of the input current i_{In}, and an initialization time for which the output voltage V_{Out} is normally initialized, i.e., the deadtime is differently shown.

Specifically, referring to FIG. 7, when applying the preamplifier 100 according to an exemplary embodiment of the present disclosure, in a case where the generation speed of the input current inn is relatively fast (A), the deadtime is measured as 2.04 μs and 1.8 μs when the output voltage V_{Out} is saturated for 3.73 μs and 2.76 μs, while in a case where the generation speed of the input current inn is relatively slow (B), the deadtime is measured as 3 μs when the output voltage V_{Out} is saturated for 7.44 μs.

In other words, referring to FIG. 7, it can be seen that according to an exemplary embodiment of the present disclosure, the preamplifier 100 may control the deadtime to be reduced as the generation speed of the input current inn is faster.

According to the above description, the preamplifier 100 initializes the circuit by using the comparator 130 and the Monostable circuit 140 to prevent saturation of the output signal V_{Out} in the high radiation environment in which a large amount of radiation is generated.

Further, the preamplifier 100 reduces a duration of an output pulse (switching signal) through incomplete discharging of the Monostable capacitor (C_{M}) 142 to reduce a deadtime in which the input current i_{In} is omitted upon circuit initialization.

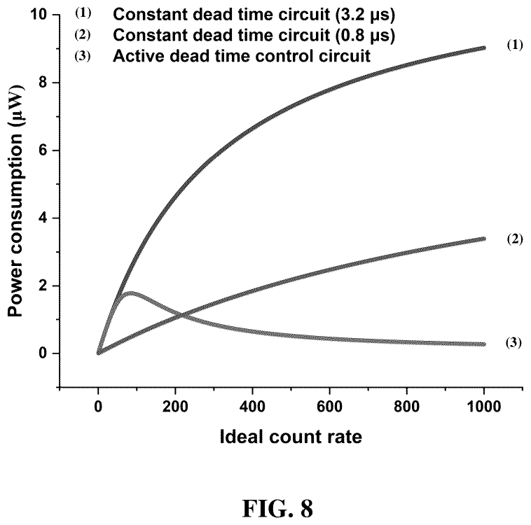

FIG. 8 is a diagram for comparing power consumption for the preamplifier with an active deadtime control circuit according to an exemplary embodiment of the present disclosure and a preamplifier having a constant deadtime in the related art.

In FIG. 8, the horizontal axis represents the number of signals input into the preamplifier 100 in a radiation instrument, and the vertical axis represents power consumption according to the number of signals.

Further, FIG. 8 may illustrate power consumption of the preamplifier 100 according to an exemplary embodiment of the present disclosure, power consumption of a preamplifier having a constant deadtime of 3.2 μs, and power consumption of a preamplifier having a constant deadtime of 0.8 μs.

The preamplifier having the constant deadtime of 3.2 μs measures signals 211 times when 650 signals are input into the preamplifier for 1 ms, and the preamplifier having the constant deadtime of 0.8 μs measures signals 427 times when 650 signals are input into the preamplifier for 1 ms. In contrast, the preamplifier 100 according to an exemplary embodiment of the present disclosure measures signals 446 times when 650 signals are input into the preamplifier for 1 ms, and measures most signals so that an omission rate is the lowest compared to the preamplifier in the related art.

Further, like the preamplifier having the constant deadtime of 3.2 μs and the preamplifier having the constant deadtime of 0.8 μs, in the circuit having the constant deadtime, as the number of input times of an input signal increases, and the deadtime is longer, more charges are consumed, so required power increases, and as a result, the power consumptions of the preamplifier having the constant deadtime of 3.2 μs and the preamplifier having the constant deadtime of 0.8 μs continuously increase.

In contrast, in the preamplifier 100 according to an exemplary embodiment of the present disclosure, when the number of input times of an input signal is small, the Monostable capacitor (C_{M}) 142 is sufficiently discharged, so the power consumption increases like the circuit having the constant deadtime, but since the Monostable capacitor (C_{M}) 142 is not sufficiently discharged as the number of input signals increases, the number of remaining charges increases, and as a result, the number of consumed charges decrease, so the power consumption is reduced.

In other words, the preamplifier 100 according to an exemplary embodiment of the present disclosure reduces the power consumption through the incomplete discharging of the Monostable capacitor (C_{M}) 142 to enhance radiation measurement efficiency and power efficiency.

Hereinafter, an operation flow of the present disclosure will be described in brief based on the contents described in detail.

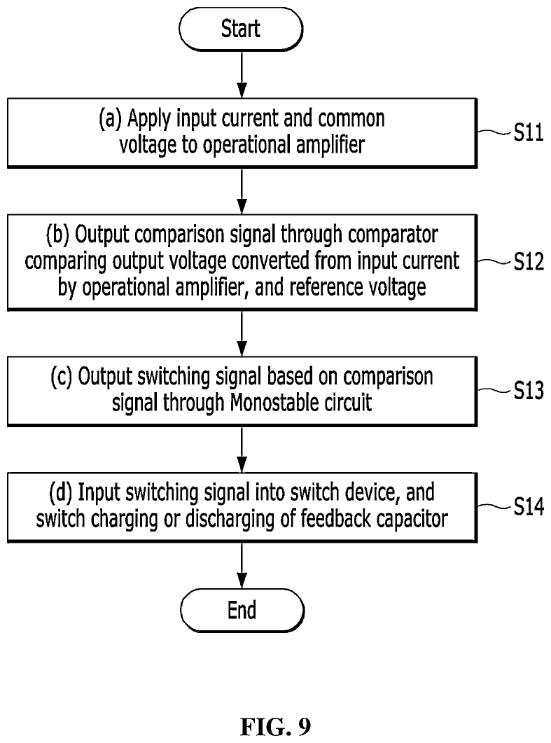

FIG. 9 is an operation flowchart for a method for driving the preamplifier with an active deadtime control circuit according to an exemplary embodiment of the present disclosure.

The method for driving the preamplifier with the active deadtime control circuit illustrated in FIG. 9 may be performed by the preamplifier 100 with the active deadtime control circuit described above. Accordingly, in spite of the contents omitted below, contents described regarding the preamplifier 100 with the active deadtime control circuit may also be similarly applied to the description of the method for driving the preamplifier with the active deadtime control circuit.

Referring to FIG. 9, in step S11, the operational amplifier 110 may be applied with input current in and common voltage V_{CM}. Specifically, the operational amplifier 110 may receive the input current inn generated from a radiation instrument through a first input terminal, and receive the common voltage V_{CM} through a second input terminal.

Next, in step S12, the comparator 130 compares the output voltage V_{Out} converted from the input current inn by the operational amplifier 110, and reference voltage V_{ref} to output a comparison signal.

Next, in step S13, the Monostable circuit 140 may output a switching signal for switching charging or discharging of the feedback capacitor 120 based on the comparison signal. At this time, both ends of the feedback capacitor 120 may be connected to the first input terminal of the operational amplifier 110 to which the input current i_{In} is applied, and an output terminal of the operational amplifier 110.

Next, in step S14, the switch device 150 may switch charging or discharging of the feedback capacitor 120 by inputting the switching signal. At this time, both ends of the switch device 150 may be connected to the first input terminal of the operational amplifier 110, and the output terminal of the operational amplifier 110.

Hereinafter, the method for driving the Monostable circuit will be described.

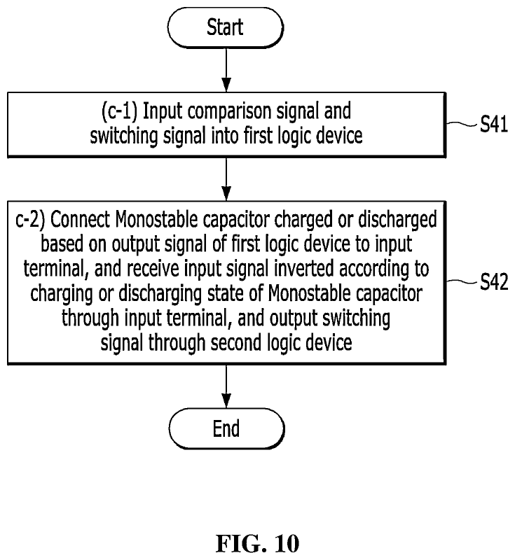

FIG. 10 is an operation flowchart for a method for driving a Monostable circuit of the preamplifier with an active deadtime control circuit according to an exemplary embodiment of the present disclosure.

The method for driving the Monostable circuit of the preamplifier with the active deadtime control circuit illustrated in FIG. 10 may be performed by the preamplifier 100 with the active deadtime control circuit described above. Accordingly, in spite of the contents omitted below, contents described regarding the preamplifier 100 with the active deadtime control circuit may also be similarly applied to the description of the method for driving the Monostable circuit of the preamplifier with the active deadtime control circuit.

Referring to FIG. 10, in step S41, the first logic device 141 may receive the comparison signal and the switching signal.

Next, in step S42, the second logic device 143 may receive an input signal inverted according to a charging or discharging state of a Monostable capacitor (C_{M}) 142 through an input terminal, and output the switching signal. At this time, an input terminal of the second logic device 143 may be connected to the Monostable capacitor (C_{M}) 142.

Further, one end of the Monostable capacitor (C_{M}) 142 is connected to an output terminal of the first logic device 141, so the Monostable capacitor (C_{M}) 142 may be charged or discharged based on an output signal of the first logic device 141. Further, the Monostable capacitor (C_{M}) 142 may be charged when the output signal of the first logic device 141 is low and discharged when the output signal of the first logic device 141 is high.

In the above description, steps S11 to S14, and steps S41 and S42 may further be divided into additional steps, or combined as fewer steps according to an implementation example of the present disclosure. Further, some steps may also be omitted as necessary, and an order between the steps may be changed.

Meanwhile, the method for driving the preamplifier with the active deadtime control circuit according to an exemplary embodiment of the present disclosure is implemented in a form of a program command which may be performed through various computer means and may be recorded in the computer readable medium. The computer readable medium may include a program command, a data file, a data structure, etc., singly or combinationally. The program command recorded in the medium may be specially designed and configured for the present disclosure, or may be publicly known to and used by those skilled in the computer software field.

An example of the computer readable recording medium includes magnetic media, such as a hard disk, a floppy disk, and a magnetic tape, optical media such as a CD-ROM and a DVD, magneto-optical media such as a floptical disk, and hardware devices such as a ROM, a RAM, and a flash memory, which are specially configured to store and execute the program command. An example of the program command includes a high-level language code executable by a computer by using an interpreter and the like, as well as a machine language code created by a compiler. The hardware device may be configured to be operated with one or more software modules in order to perform the operation of the present disclosure and vice versa.

Further, the method for driving the preamplifier with the active deadtime control circuit may also be implemented in a form of a computer program or an application executed by the computer, which is stored in the recording medium.

The aforementioned description of the present disclosure is used for exemplification, and it can be understood by those skilled in the art that the present disclosure can be easily modified in other detailed forms without changing the technical spirit or requisite features of the present disclosure. Therefore, it should be appreciated that the aforementioned exemplary embodiments are illustrative in all aspects and are not restricted. For example, respective constituent elements described as single types can be distributed and implemented, and similarly, constituent elements described to be distributed can also be implemented in a coupled form.

The scope of the present disclosure is represented by claims to be described below rather than the detailed description, and it is to be interpreted that the meaning and scope of the claims and all the changes or modified forms derived from the equivalents thereof come within the scope of the present disclosure.

What is claimed is:

1. A preamplifier with an active deadtime control circuit, comprising:
an operational amplifier to which input current and common voltage are applied;
a feedback capacitor of which both ends are connected to a first input terminal of the operational amplifier to which the input current is applied and an output terminal of the operational amplifier;
a comparator comparing output voltage converted from the input current by the operational amplifier, and reference voltage to output a comparison signal; and
a Monostable circuit outputting a switching signal for switching charging or discharging of the feedback capacitor based on the comparison signal.

2. The preamplifier according to claim 1, wherein the Monostable circuit includes
a first logic device receiving the comparison signal and the switching signal,
a Monostable capacitor having one end connected to an output terminal of the first logic device, and charged or discharged based on an output signal of the first logic device, and
a second logic circuit having an input terminal connected to the Monostable capacitor, and receiving an input signal inverted according to a charging or discharging state of the Monostable capacitor through the input terminal, and outputting the switching signal.

3. The preamplifier according to claim 2, wherein the Monostable capacitor is charged when the output signal is low and discharged when the output signal is high.

4. The preamplifier according to claim 1, further comprising:
a switch device having both ends connected to the first input terminal of the operational amplifier and the output terminal of the operational amplifier, and switching charging or discharging of the feedback capacitor by inputting the switching signal.

5. The preamplifier according to claim 1, wherein the operational amplifier receives the input current generated from a radiation instrument through the first input terminal of the operational amplifier, and receives the common voltage through a second input terminal of the operational amplifier.

6. A method for driving a preamplifier with an active deadtime control circuit, comprising:
(a) applying input current and common voltage to an operational amplifier;
(b) outputting a comparison signal through a comparator comparing output voltage converted from the input current by the operational amplifier, and reference voltage; and
(c) outputting a switching signal for switching charging or discharging of a feedback capacitor having both ends connected to a first input terminal of the operational amplifier to which the input current is applied, and an output terminal of the operational amplifier based on the comparison signal through a Monostable circuit.

7. The method according to claim 6, wherein the step (c) includes
(c-1) inputting the comparison signal and the switching signal into a first logic device, and
(c-2) connecting a Monostable capacitor having one end connected to an output terminal of the first logic device, and charged or discharged based on an output signal of the first logic device to an input terminal, and receiving an input signal inverted according to a charging or discharging state of the Monostable capacitor through the input terminal, and outputting the switching signal through a second logic device.

8. The method according to claim 7, wherein the Monostable capacitor is charged when the output signal is low and discharged when the output signal is high.

9. The method according to claim 6, further comprising:
(d) inputting the switching signal into a switch device having both ends connected to the first input terminal of the operational amplifier and the output terminal of the operational amplifier, and switching charging or discharging of the feedback capacitor.

10. The method according to claim 6, wherein the operational amplifier receives the input current generated from a radiation instrument through the first input terminal of the operational amplifier, and receives the common voltage through a second input terminal of the operational amplifier.
